(19) United States
(12) Patent Application Publication
(10) Pub. No.: US 2026/0068635 A1
(43) Pub. Date: Mar. 5, 2026

(54) CONTACT STRUCTURE, SEMICONDUCTOR DEVICE COMPRISING A CONTRACT STRUCTURE, AND METHOD FOR FABRICATING THE SEMICONDUCTOR DEVICE

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/825,237

(22) Filed: Sep. 5, 2024

(51) Int. Cl. H01L 23/528

(52) U.S. Cl. CPC H01L 23/528

(57) ABSTRACT

The present application discloses a contact structure, a semiconductor device including the contact structure, and a method for fabricating the semiconductor device. The contact structure includes a body portion, and an extending portion extending downward from the body portion and comprising a groove. The groove is recessed into a bottom surface of the extending portion, is recessed toward the body portion, and exposes the body portion.

### TECHNICAL FIELD

The present disclosure relates to a contact structure, a semiconductor device with a contact structure, and a method for fabricating the semiconductor device, and more particularly, to a contact structure with an extending portion.

### DISCUSSION OF THE BACKGROUND

Semiconductor devices are used in various electronic applications, including personal computers, cellular telephones, digital cameras, and other electronic equipment. Sizes of semiconductor devices are continuously decreasing to meet growing demands for computing power. However, such scaling down presents challenges that are becoming more frequent and impactful. Therefore, there are still challenges to overcome in improving quality, yield, performance and reliability while reducing complexity.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device comprising a substrate; a word line structure comprising a word line electrode; an impurity region comprising an upper portion adjacent to the word line structure and a lower portion below the upper portion; and a contact structure comprising a body portion over the impurity region and an extending portion below the body portion. A top surface of the word line electrode of the word line structure is lower than a top surface of the upper portion of the impurity region, and the upper portion of the impurity region has a tapered cross-sectional profile.

Another aspect of the present disclosure provides a semiconductor device comprising a substrate with an isolation layer disposed therein; a plurality of impurity regions disposed in an active area defined by the isolation layer; and a plurality of first word line structures disposed in the isolation layer and a plurality of second word line structures disposed in the active area.

Another aspect of the present disclosure provides a semiconductor device comprising a substrate; a word line structure disposed in the substrate; an impurity region comprising an upper portion adjacent to the word line structure and a lower portion disposed below the upper portion; a bit line contact disposed in the substrate and protruding from the substrate; and a bit line disposed on the bit line contact. The word line structure comprises a word line dielectric layer contacting the lower portion of the impurity region, a word line electrode disposed on the word line dielectric layer, and a word line capping layer disposed on the word line electrode. A top surface of the word line electrode of the word line structure is lower than a top surface of the upper portion of the impurity region. The upper portion of the impurity region has a tapered cross-sectional profile.

Due to a design of the semiconductor device of the present disclosure, an extending portion may increase a contact area of a contact structure. As a result, performance of the semiconductor device may be improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiments disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in flowchart diagram form, a method for fabricating a semiconductor device in accordance with one embodiment of the present disclosure.

FIGS. 2 to 10 illustrate, in schematic cross-sectional view diagrams, a process for fabricating the semiconductor device in accordance with one embodiment of the present disclosure.

FIG. 11 illustrates, in a schematic top-view diagram, an intermediate semiconductor device in accordance with one embodiment of the present disclosure.

FIG. 12 is a schematic cross-sectional view diagram taken along a line A-A′ in FIG. 11.

FIG. 13 illustrates, in a schematic top-view diagram, an intermediate semiconductor device in accordance with one embodiment of the present disclosure.

FIG. 14 is a schematic cross-sectional view diagram taken along a line A-A′ in FIG. 13.

FIG. 15 illustrates, in a schematic top-view diagram, an intermediate semiconductor device in accordance with one embodiment of the present disclosure.

FIGS. 16 and 17 are schematic cross-sectional view diagrams taken along a line A-A′ in FIG. 15 illustrating a process for fabricating the semiconductor device in accordance with one embodiment of the present disclosure.

FIG. 18 illustrates, in a schematic top-view diagram, an intermediate semiconductor device in accordance with one embodiment of the present disclosure.

FIG. 19 is a schematic cross-sectional view diagram taken along a line A-A′ in FIG. 18.

FIG. 20 illustrates, in a schematic top-view diagram, an intermediate semiconductor device in accordance with one embodiment of the present disclosure.

FIG. 21 is a schematic cross-sectional view diagram taken along a line A-A′ in FIG. 20.

FIG. 22 illustrates, in a schematic top-view diagram, an intermediate semiconductor device in accordance with one embodiment of the present disclosure.

FIGS. 23 to 26 are schematic cross-sectional view diagrams taken along a line A-A′ in FIG. 22 illustrating a process for fabricating the semiconductor device in accordance with one embodiment of the present disclosure.

FIG. 27 is a schematic cross-sectional view diagram taken along lines B-B′ and C-C′ in FIG. 26.

FIGS. 28 and 29 illustrate, in schematic cross-sectional view diagrams, body portions and extending portions of semiconductor devices in accordance with some embodiments of the present disclosure.

FIG. 30 illustrates, in a schematic cross-sectional view diagram, a semiconductor device in accordance with another embodiment of the present disclosure.

FIG. 31 illustrates, in a schematic cross-sectional view diagram, a semiconductor device in accordance with various embodiment of the present disclosure.

FIGS. 32 to 33 illustrate, in schematic cross-sectional view diagrams, a process for fabricating the semiconductor device in accordance with various embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the direction Z, and below (or down) corresponds to the opposite direction of the arrow of the direction Z.

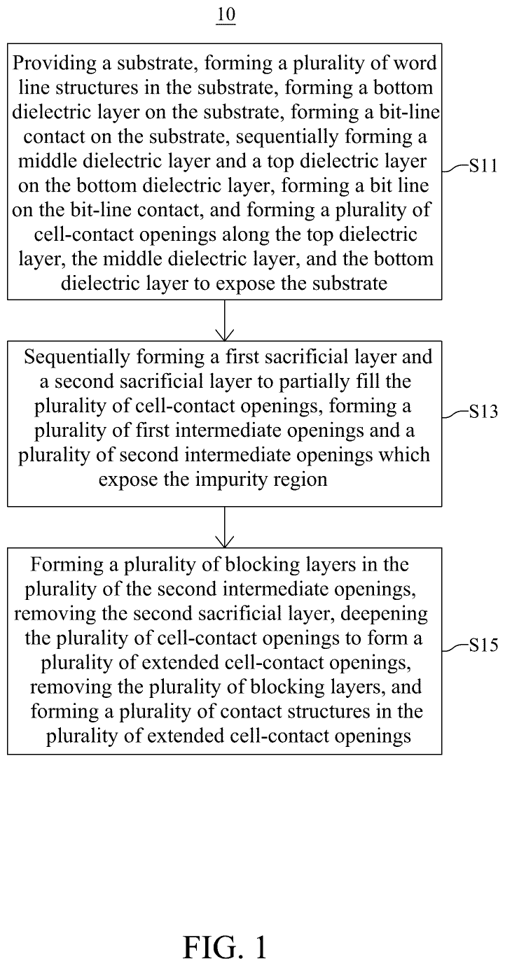

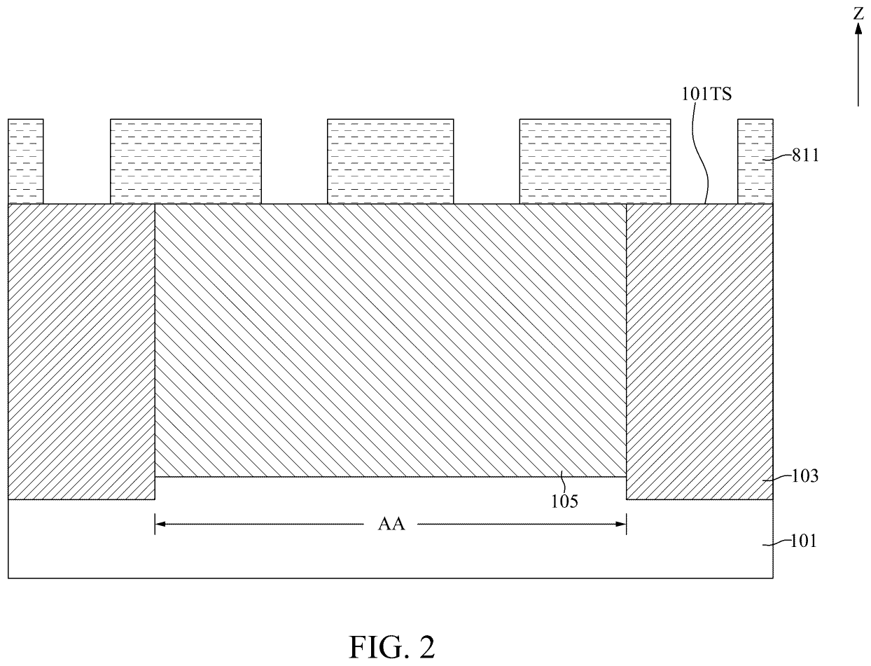

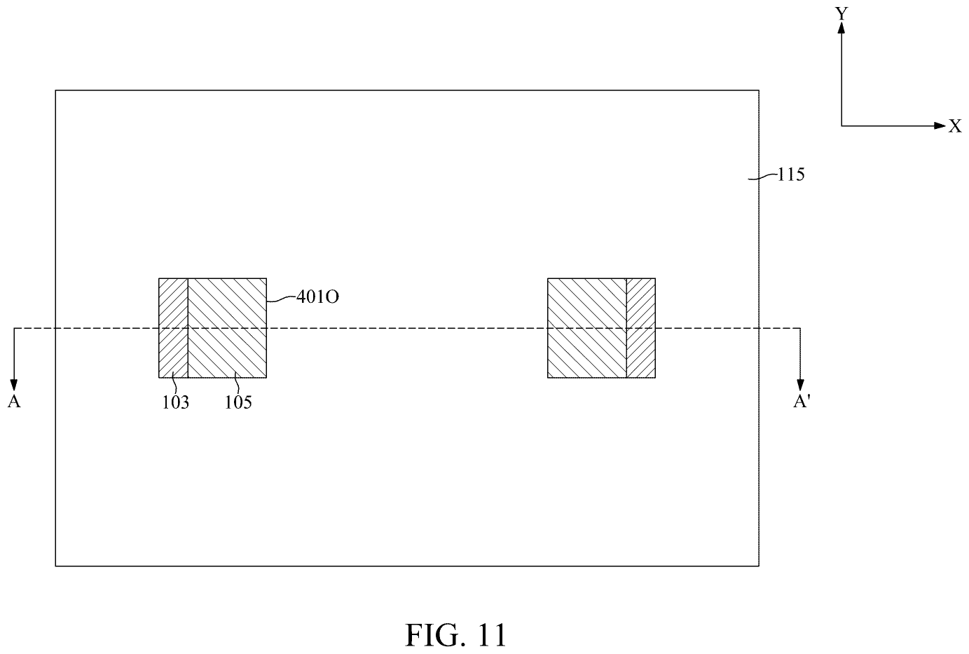

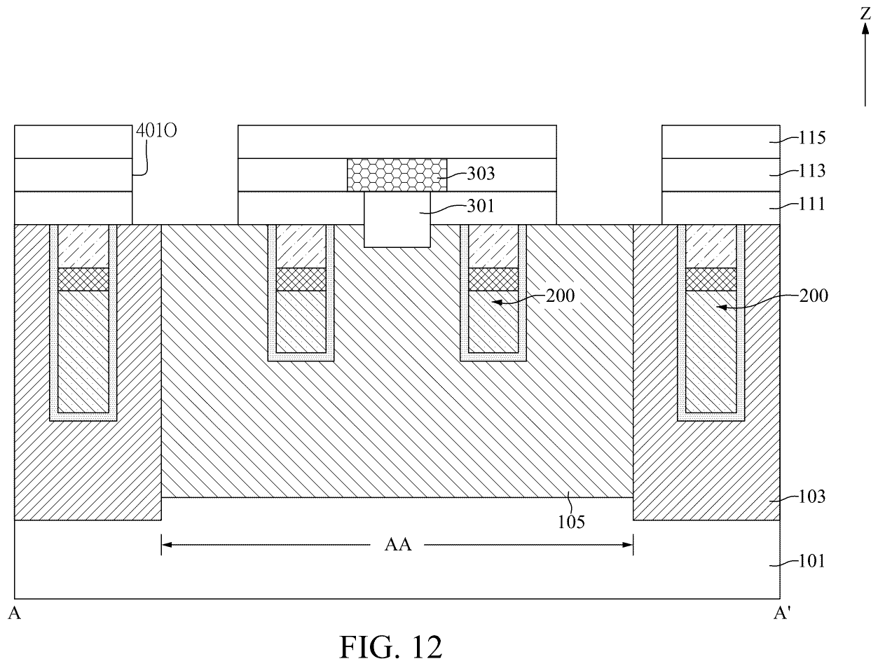

FIG. 1 illustrates, in flowchart diagram form, a method 10 for fabricating a semiconductor device in accordance with one embodiment of the present disclosure. FIGS. 2 to 10 illustrate, in schematic cross-sectional view diagrams, a process for fabricating a semiconductor device in accordance with one embodiment of the present disclosure. FIG. 11 illustrates, in a schematic top-view diagram, an intermediate semiconductor device in accordance with one embodiment of the present disclosure. FIG. 12 is a schematic cross-sectional view diagram taken along a line A-A′ in FIG. 11.

With reference to FIGS. 1 to 10, in step S11, a substrate 101 may be provided, a plurality of word line structures 200 may be formed in the substrate 101, a bottom dielectric layer 111 may be formed on the substrate 101, a bit line contact 301 may be formed on the substrate 101, a middle dielectric layer 113 and a top dielectric layer 115 may be sequentially formed on the bottom dielectric layer 111, a bit line 303 may be formed on the bit line contact 301, and a plurality of cell contact openings 401O may be formed in the top dielectric layer 115, the middle dielectric layer 113, and the bottom dielectric layer 111 to expose the substrate 101.

With reference to FIG. 2, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, another III-V compound semiconductor or II-VI compound semiconductor, or a combination thereof.

With reference to FIG. 2, an isolation layer 103 may be formed in the substrate 101. A series of deposition processes may be performed to deposit a pad oxide layer (not shown) and a pad nitride layer (not shown) on the substrate 101. A photolithography process and a subsequent etching process, such as an anisotropic dry etching process, may be performed to form trenches penetrating through the pad oxide layer and the pad nitride layer and extending into the substrate 101. An insulating material may be deposited in the trenches and a planarization process, such as chemical mechanical polishing, may be subsequently performed until a top surface 101TS of the substrate 101 is exposed to remove excess filling material, provide a substantially flat surface for subsequent processing steps, and concurrently form the isolation layer 103. The insulating material may be, for example, silicon oxide or other applicable insulating materials. In some embodiments, the isolation layer 103 may define an active area AA in the substrate 101.

With reference to FIG. 2, an impurity region 105 may be formed in the active area AA. In some embodiments, the impurity region 105 may be formed by an implantation process using p-type dopants or n-type dopants. The impurity region 105 may serve as a source and/or a drain for the semiconductor device 1A.

The term “p-type dopant” refers to an impurity that, when added to an intrinsic semiconductor material, creates deficiencies of valence electrons. In a silicon-containing semiconductor material, examples of p-type dopants include, but are not limited to, boron, aluminum, gallium, and indium. The term “n-type dopant” refers to an impurity that, when added to an intrinsic semiconductor material, contributes free electrons to the intrinsic semiconductor material. In a silicon-containing material, examples of n-type dopants include, but are not limited to, antimony, arsenic, and phosphorus.

With reference to FIG. 2, a first mask layer 811 may be formed on the substrate 101. In some embodiments, the first mask layer 811 may be a photoresist layer and may include a pattern of the plurality of word line structures 200.

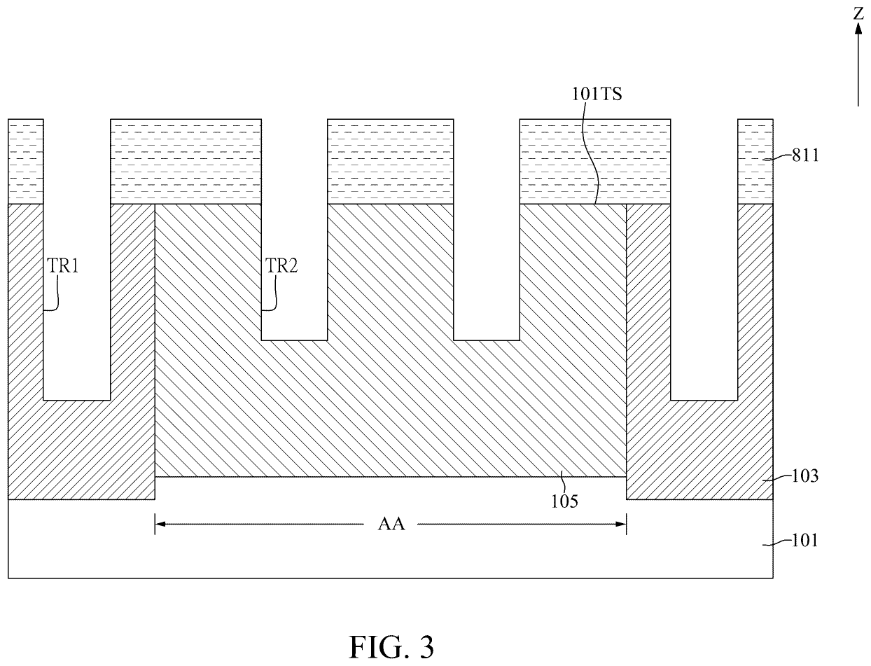

With reference to FIG. 3, a trench etching process may be performed using the first mask layer 811 as a mask to remove portions of the isolation layer 103 and portions of the substrate 101, and concurrently form a plurality of trenches TR1, TR2. In some embodiments, the plurality of trenches TR2 formed in the substrate 101 may be shallower than the plurality of trenches TR1 formed in the isolation layer 103. After the formation of the plurality of trenches TR1, TR2, the first mask layer 811 may be removed.

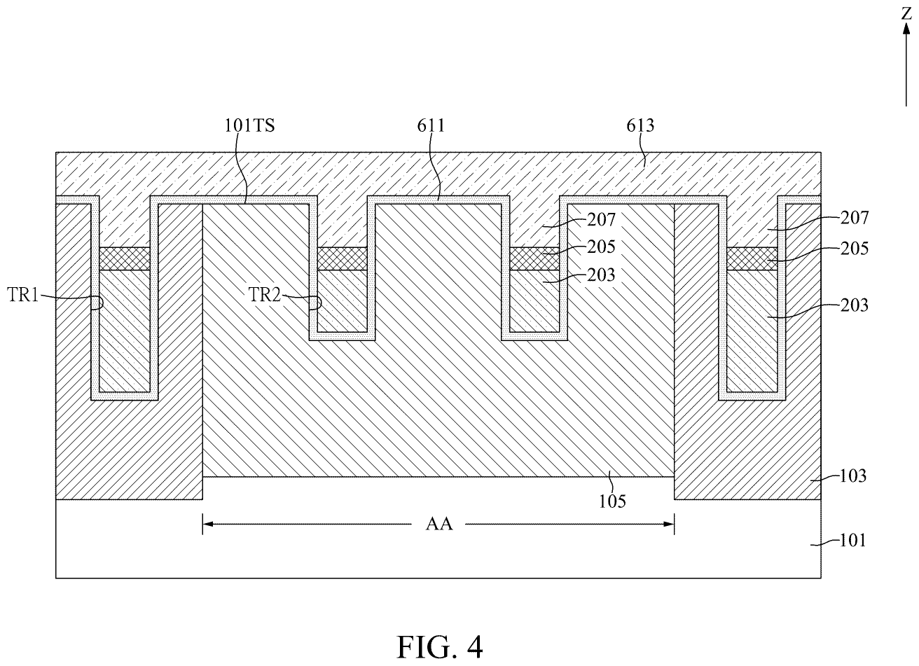

With reference to FIG. 4, a layer of first insulating material 611 may be conformally formed on the substrate 101, on the isolation layer 103, and in the plurality of trenches TR1, TR2. The layer of first insulating material 611 may have a U-shaped cross-sectional profile in the plurality of trenches TR1, TR2. In some embodiments, the layer of first insulating material 611 may have a thickness in a range of about 1 nm to about 7 nm, including about 1 nm, about 2 nm, about 3 nm, about 4 nm, about 5 nm, about 6 nm, or about 7 nm.

In some embodiments, the layer of first insulating material 611 may be formed by a thermal oxidation process. For example, the layer of first insulating material 611 may be formed by oxidizing a surface of the plurality of trenches TR1, TR2. In some embodiments, the layer of first insulating material 611 may be formed by a deposition process such as a chemical vapor deposition or an atomic layer deposition. The first insulating material 611 may include a high-k dielectric material, an oxide, a nitride, an oxynitride, or a combination thereof. In some embodiments, after a liner polysilicon layer (not shown) is deposited, the layer of first insulating material 611 may be formed by radically oxidizing the liner polysilicon layer. In some embodiments, after a liner silicon nitride layer (not shown) is formed, the layer of first insulating material 611 may be formed by radically oxidizing the liner silicon nitride layer.

In some embodiments, the high-k dielectric material may include a hafnium-containing material. The hafnium-containing material may be, for example, hafnium oxide, hafnium silicon oxide, hafnium silicon oxynitride, or a combination thereof. In some embodiments, the high-k dielectric material may be, for example, lanthanum oxide, lanthanum aluminum oxide, zirconium oxide, zirconium silicon oxide, zirconium silicon oxynitride, aluminum oxide, or a combination thereof.

With reference to FIG. 4, a plurality of word line bottom conductive layers 203 may be formed in the plurality of trenches TR1, TR2, respectively and correspondingly. For example, a conductive material (not shown) may be formed to fill the plurality of trenches TR1, TR2. An etch-back process may be subsequently performed to partially remove the conductive material formed in the plurality of trenches TR1, TR2 and concurrently form the plurality of word line bottom conductive layers 203. In some embodiments, the conductive material may be a work function material, such as titanium, titanium nitride, silicon, silicon germanium, or a combination thereof. It should be noted that the term “work function” refers to a bulk chemical potential of a material (e.g., a metal) relative to a vacuum level. For example, in one embodiment, the conductive material is titanium nitride and may be formed by chemical vapor deposition.

With reference to FIG. 4, a plurality of word line top conductive layers 205 may be formed in the plurality of trenches TR1, TR2. In some embodiments, the plurality of word line top conductive layers 205 may be formed of, for example, polycrystalline silicon, polycrystalline germanium, polycrystalline silicon germanium, doped polycrystalline silicon, doped polycrystalline germanium, doped polycrystalline silicon germanium, or a combination thereof. In some embodiments, the plurality of word line top conductive layers 205 may be doped with p-type dopants or n-type dopants. In some embodiments, a conductive material such as polycrystalline silicon, polycrystalline germanium, or polycrystalline silicon germanium may be deposited in the plurality of trenches TR1, TR2. An etch-back process may be subsequently performed to remove portions of the conductive material to form the plurality of word line top conductive layers 205. In some embodiments, the dopants may be incorporated in a deposition process of the conductive material. In some embodiments, the dopants may be implanted using an implantation process after the etch-back process.

With reference to FIG. 4, a word line capping layer 207 may be formed to completely fill the plurality of trenches TR1, TR2. In some embodiments, the word line capping layer 207 may be formed of, for example, silicon nitride, silicon oxynitride, silicon nitride oxide, or other applicable dielectric materials. In some embodiments, the word line capping layer 207 may be formed by, for example, chemical vapor deposition, plasma-enhanced chemical vapor deposition, or other applicable deposition processes.

It should be noted that, in the present disclosure, silicon oxynitride refers to a substance which contains silicon, nitrogen, and oxygen and in which a proportion of oxygen is greater than that of nitrogen. Silicon nitride oxide refers to a substance which contains silicon, oxygen, and nitrogen and in which a proportion of nitrogen is greater than that of oxygen.

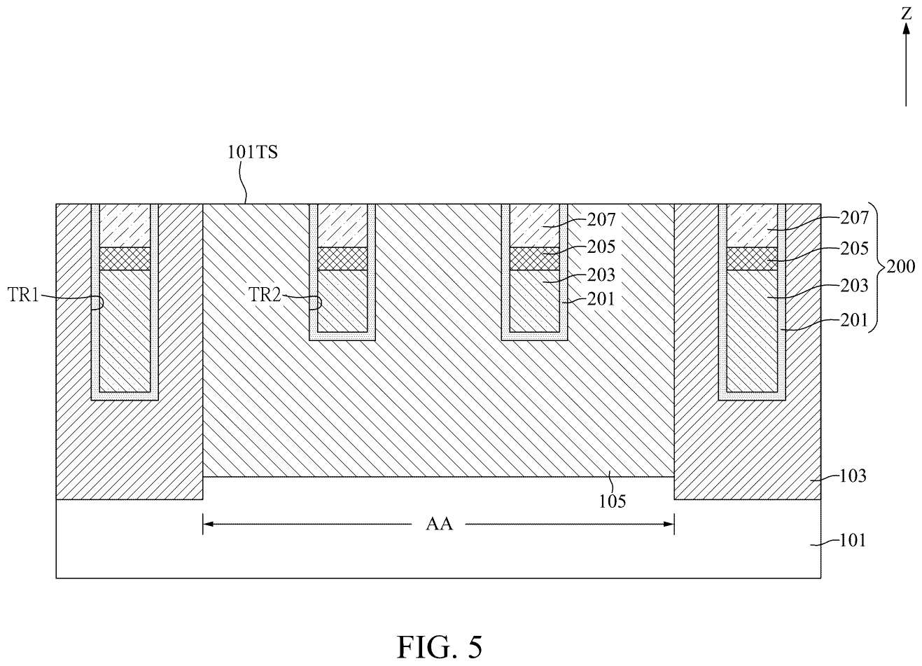

With reference to FIG. 5, a planarization process, such as chemical mechanical polishing, may be performed until the top surface 101TS of the substrate 101 is exposed to remove excess material and provide a substantially flat surface for subsequent processing steps. After the planarization process, the layer of first insulating material 611 may be turned into a plurality of word line dielectric layers 201 in the plurality of trenches TR1, TR2, respectively and correspondingly. The word line capping layer 207 may be turned into multiple segments and may be formed on the plurality of word line top conductive layers 205, respectively and correspondingly. The plurality of word line dielectric layers 201, the plurality of word line bottom conductive layers 203, the plurality of word line top conductive layers 205, and the plurality of word line capping layers 207 together configure the plurality of word line structures 200. It should be noted that while the word line structure 200 in the trench TR1 and the word line structure 200 in the trench TR2 differ in dimensions, their layer compositions remain the same.

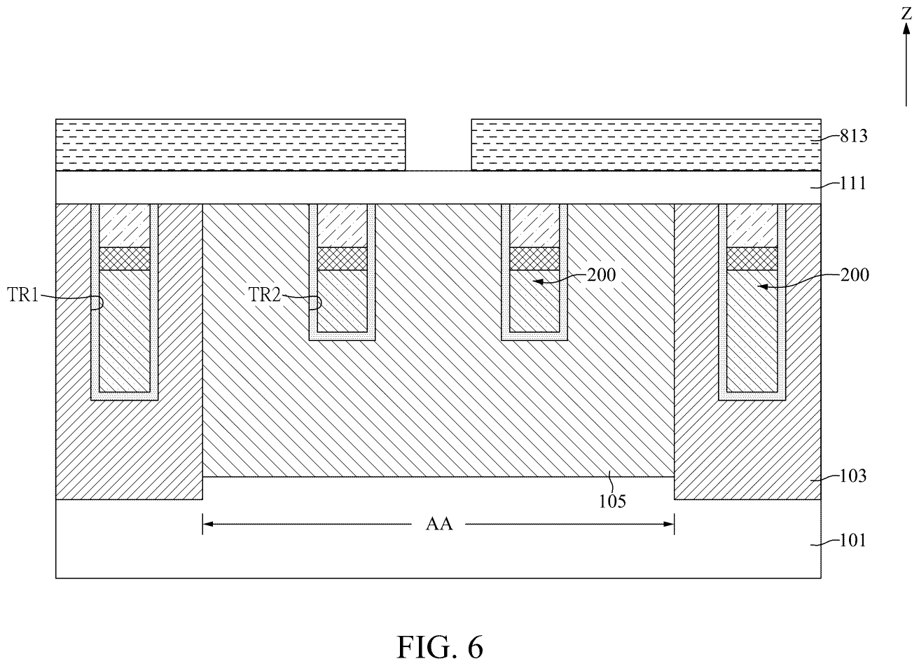

With reference to FIG. 6, a bottom dielectric layer 111 may be formed on the substrate 101. In some embodiments, the bottom dielectric layer 111 may be formed of, for example, silicon oxide, undoped silicate glass, fluorosilicate glass, borophosphosilicate glass, a spin-on low-k dielectric layer, a chemical vapor deposition low-k dielectric layer, or a combination thereof. The term “low-k” as used throughout the present disclosure denotes a dielectric material that has a dielectric constant less than that of silicon oxide. In some embodiments, the bottom dielectric layer 111 may include a self-planarizing material such as a spin-on glass or a spin-on low-k dielectric material such as SiLK™. The use of a self-planarizing dielectric material may eliminate a need to perform a subsequent planarizing step. In some embodiments, the bottom dielectric layer 111 may be formed by a deposition process including, for example, chemical vapor deposition, plasma-enhanced chemical vapor deposition, evaporation, or spin-on coating.

With reference to FIG. 6, a second mask layer 813 may be formed on the bottom dielectric layer 111. In some embodiments, the second mask layer 813 may be a photoresist layer and may include a pattern of the bit line contact 301.

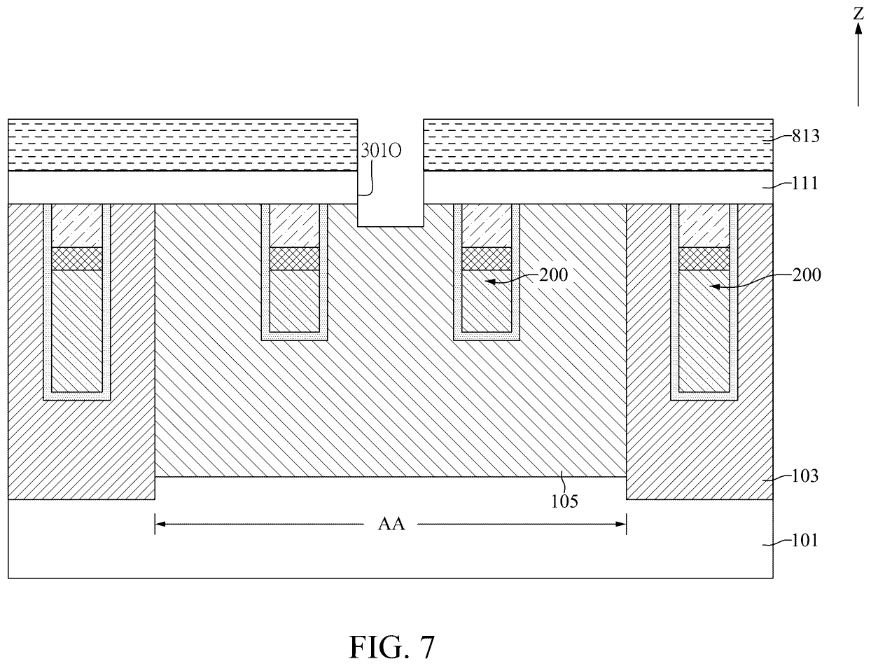

With reference to FIG. 7, a bit line contact etching process may be performed using the second mask layer 813 as a mask to remove a portion of the bottom dielectric layer 111 and a portion of the impurity region 105, and concurrently form a bit line contact opening 3010. The bit line contact opening 3010 may extend into the impurity region 105 and may be between the word line structures 200 formed in the trenches TR2. After formation of the bit line contact opening 3010, the second mask layer 813 may be removed.

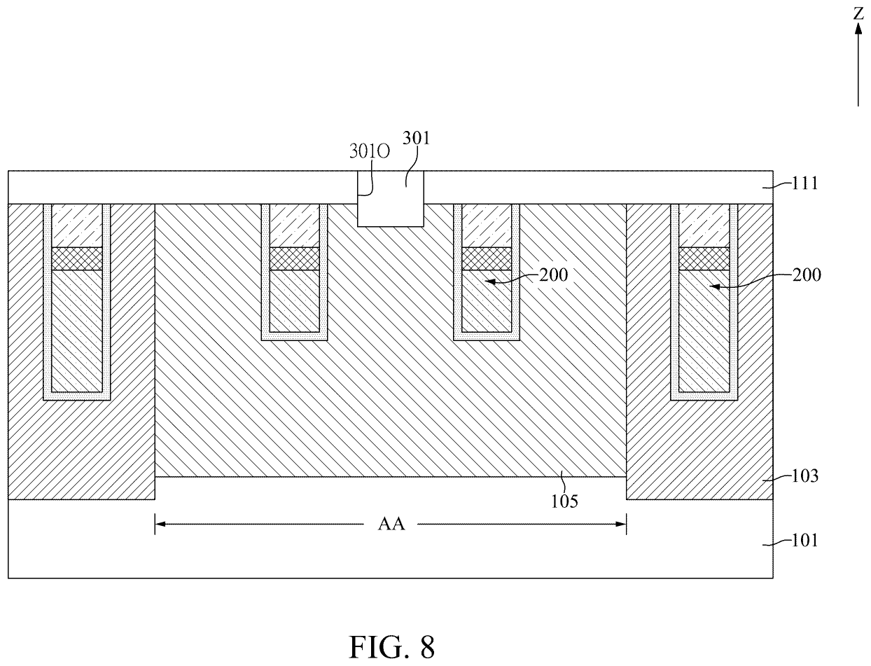

With reference to FIG. 8, the bit line contact 301 may be formed in the bit line contact opening 3010 by depositing a conductive material and subsequently conducting a planarization process, such as chemical mechanical polishing. In some embodiments, the conductive material may be, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof. The bit line contact 301 may be electrically connected to the impurity region 105.

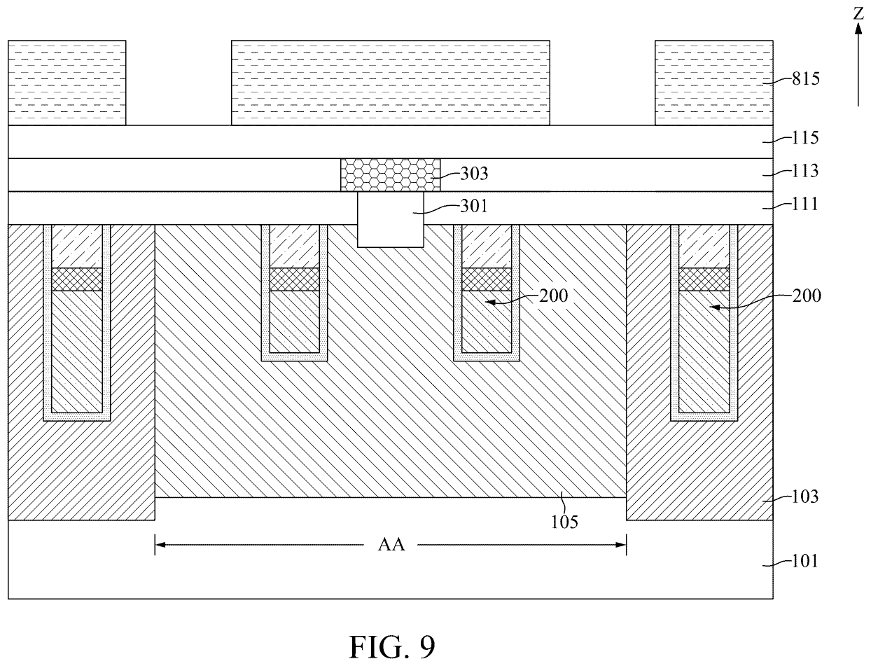

With reference to FIG. 9, the middle dielectric layer 113 may be formed on the bottom dielectric layer 111. In some embodiments, the middle dielectric layer 113 may be formed of a material same as a material of the bottom dielectric layer 111, but is not limited thereto. In some embodiments, the bit line 303 may be formed in the middle dielectric layer 113 and may be formed on the bit line contact 301. The bit line 303 may be electrically coupled to the impurity region 105 through the bit line contact 301. In some embodiments, the bit line 303 may be formed of, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

With reference to FIG. 9, the top dielectric layer 115 may be formed on the middle dielectric layer 113. In some embodiments, the top dielectric layer 115 may be formed of a material same as a material of the bottom dielectric layer 111, but is not limited thereto. A third mask layer 815 may be formed on the top dielectric layer 115. In some embodiments, the third mask layer 815 may be a photoresist layer and may include a pattern of the plurality of cell contact openings 401O.

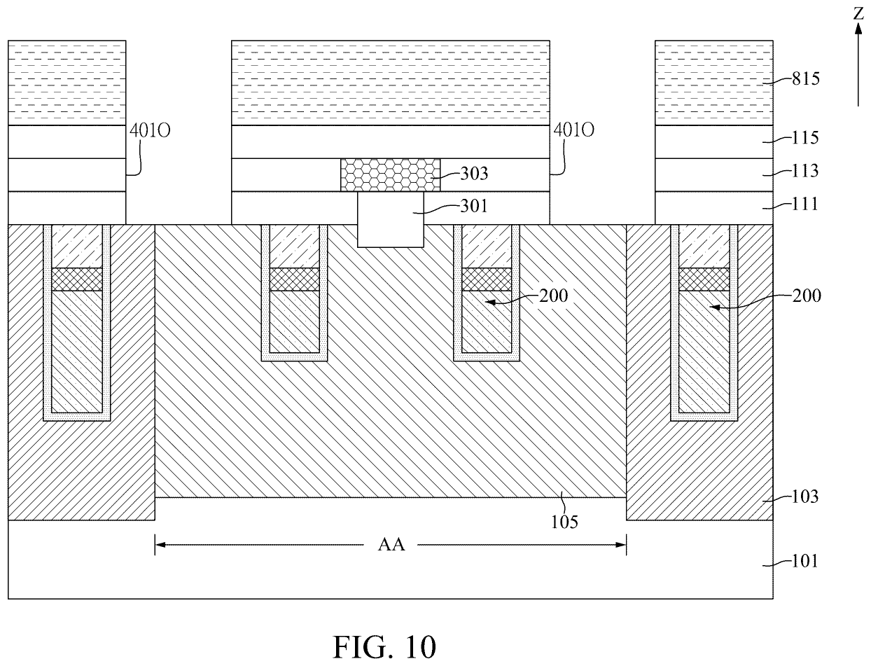

With reference to FIG. 10, a cell contact etching process may be performed using the third mask layer 815 as a mask to remove portions of the top dielectric layer 115, the middle dielectric layer 113, and the bottom dielectric layer 111. After the cell contact etching process is performed, the plurality of cell contact openings 401O may be formed through the top dielectric layer 115, the middle dielectric layer 113, and the bottom dielectric layer 111.

For brevity, clarity, and convenience of description, only one cell contact opening 401O is described.

With reference to FIGS. 11 and 12, the third mask layer 815 may be removed by an ashing process or other applicable semiconductor processes. A portion of the impurity region 105 and a portion of the isolation layer 103 may be exposed through the cell contact opening 401O. In some embodiments, from a top-view perspective, the cell contact opening 401O may include a square cross-sectional profile. In some embodiments, the cell contact opening 401O may include a rectangular cross-sectional profile (not shown).

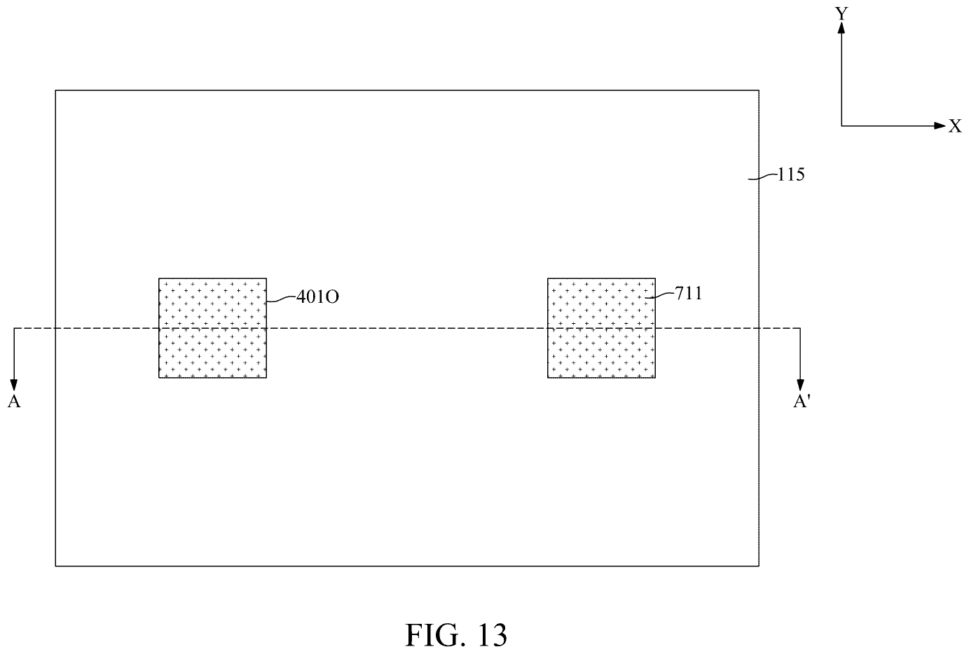

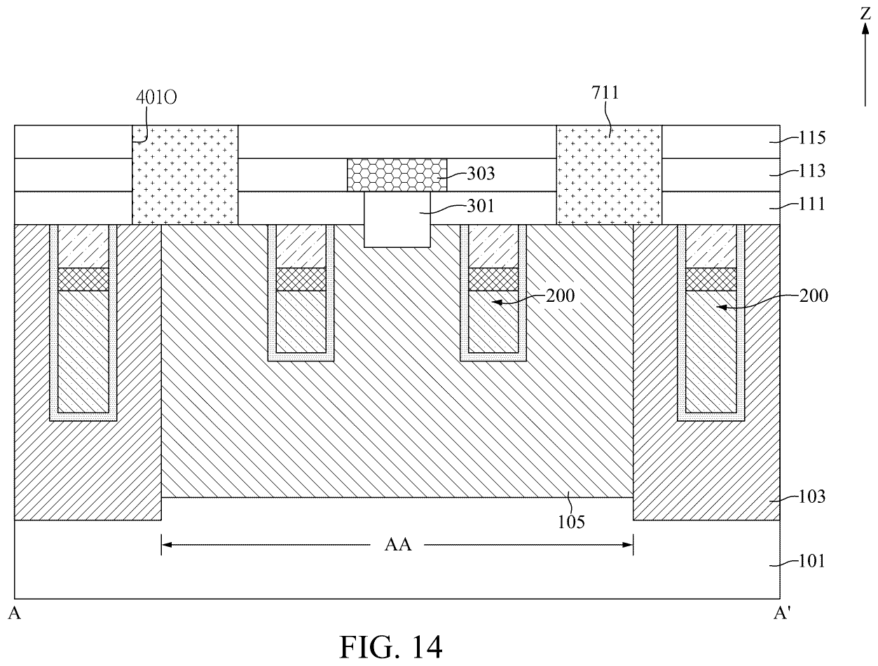

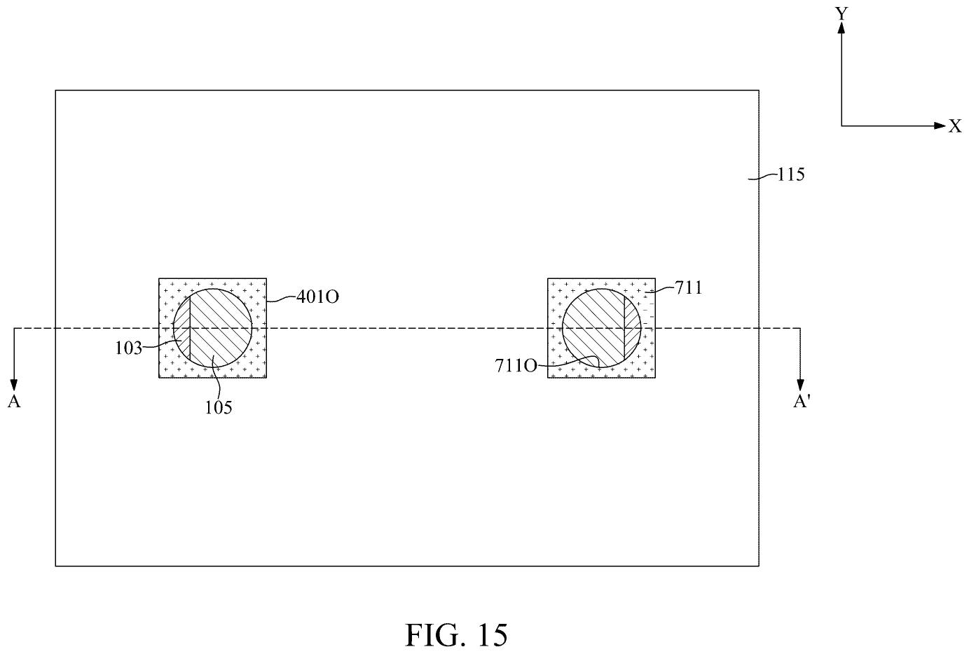

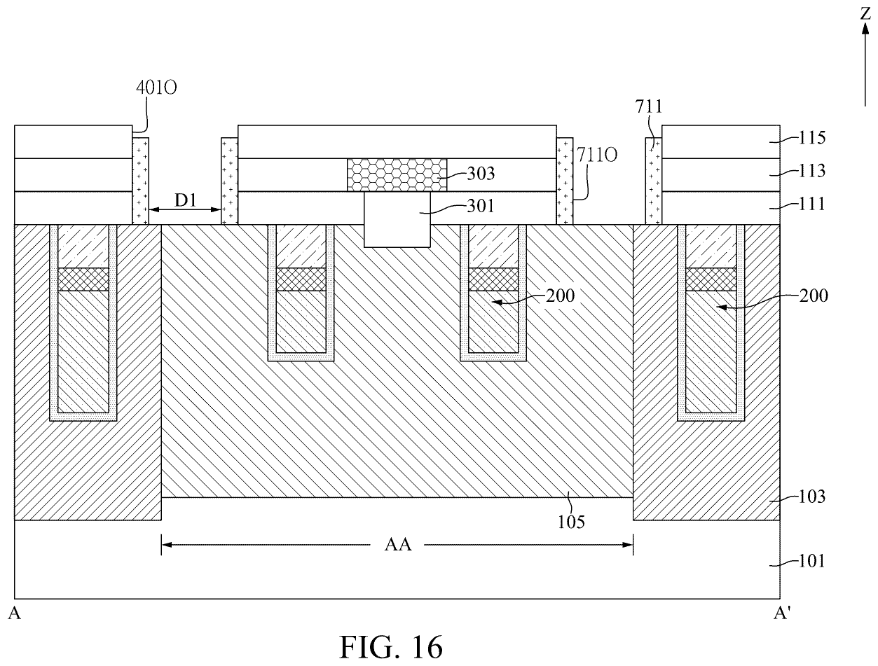

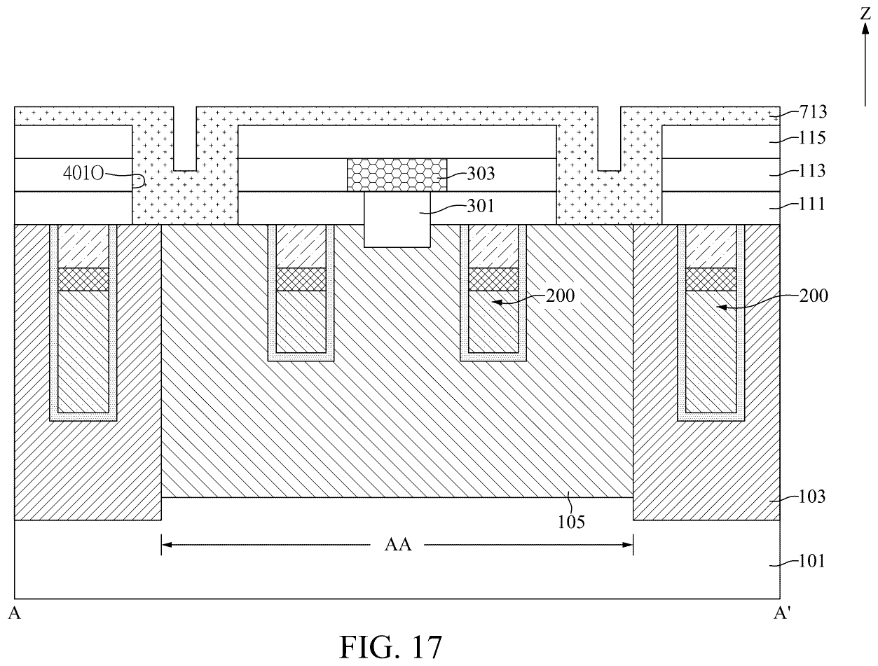

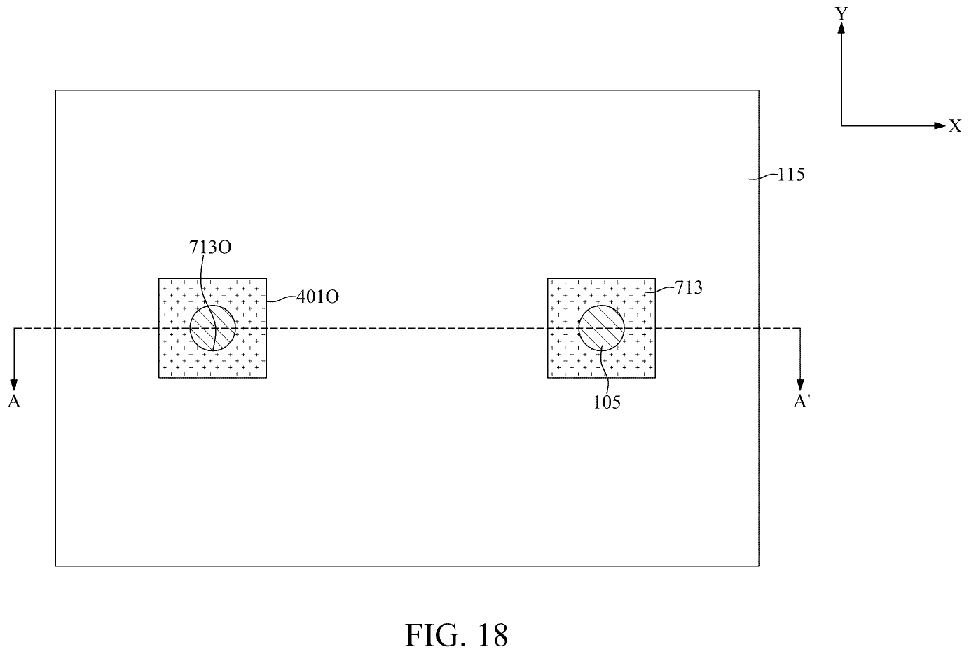

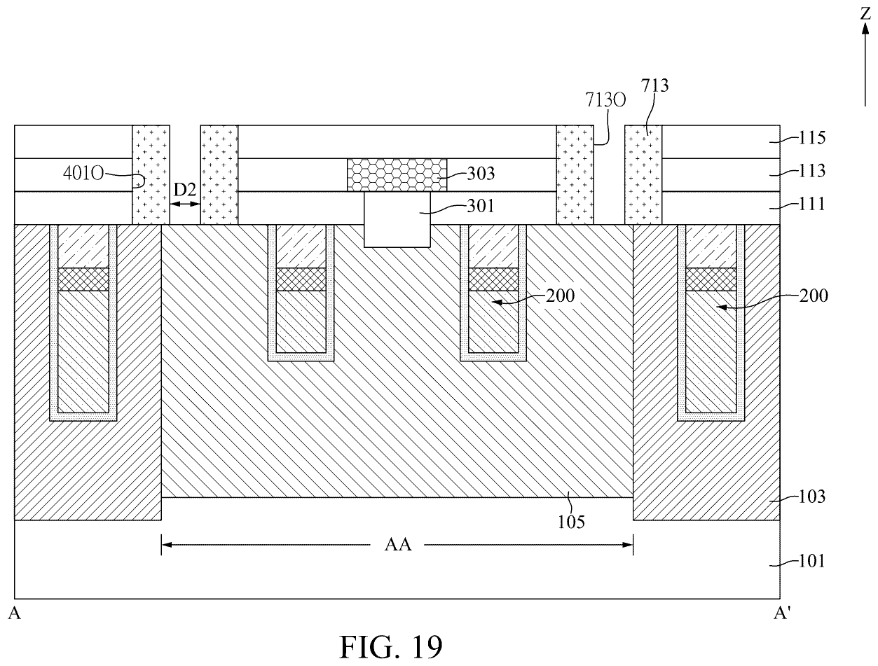

FIG. 13 illustrates, in a schematic top-view diagram, an intermediate semiconductor device in accordance with one embodiment of the present disclosure. FIG. 14 is a schematic cross-sectional view diagram taken along a line A-A′ in FIG. 13. FIG. 15 illustrates, in a schematic top-view diagram, an intermediate semiconductor device in accordance with one embodiment of the present disclosure. FIGS. 16 and 17 are schematic cross-sectional view diagrams taken along a line A-A′ in FIG. 15 illustrating a process for fabricating the semiconductor device 1A in accordance with one embodiment of the present disclosure. FIG. 18 illustrates, in a schematic top-view diagram, an intermediate semiconductor device in accordance with one embodiment of the present disclosure. FIG. 19 is a schematic cross-sectional view diagram taken along a line A-A′ in FIG. 18.

With reference to FIG. 1 and FIGS. 13 to 19, in step S13, a first sacrificial layer 711 and a second sacrificial layer 713 may be sequentially formed to partially fill the plurality of cell contact openings 401O, sequentially forming a plurality of first intermediate openings 711O and a plurality of second intermediate openings 713O which expose the impurity region 105.

An opening-tuning process may be performed to adjust an exposed portion within the cell contact opening 401O. In some embodiments, the opening-tuning process may include one deposition act followed by one etching act. A deposition act and the subsequent etching act may be referred to as a cycle. Multiple cycles may be performed during the opening-tuning process. During the deposition act, a sacrificial material may be deposited to completely fill the cell contact opening 401O. The subsequent etching act may remove part of the sacrificial material, leaving an intermediate opening inside the cell contact opening 401O. This may effectively reduce a size of the exposed portion within the cell contact opening 401O, resulting in the cell contact opening 401O being only partially filled. For a visual representation of this process, please refer to FIGS. 13 to 19, which illustrate an exemplary opening-tuning process including two cycles.

With reference to FIGS. 13 and 14, during the deposition act of a first cycle of the opening-tuning process, the first sacrificial layer 711 may be deposited to completely fill the cell contact opening 401O. The first sacrificial layer 711 may be formed of the sacrificial material. In some embodiments, the first sacrificial layer 711 may be formed by, for example, chemical vapor deposition, plasma-enhanced chemical vapor deposition, or other applicable deposition processes. A planarization process may be performed until a top surface of the top dielectric layer 115 is exposed to provide a substantially flat surface for subsequent semiconductor processes. In some embodiments, the planarization process may be optional.

In some embodiments, the sacrificial material may be a material having etching selectivity to the top dielectric layer 115 and the impurity region 105 (or the substrate 101). In some embodiments, the sacrificial material may be formed of, for example, silicon nitride, boron nitride, silicon boron nitride, phosphorus boron nitride, boron carbon silicon nitride, or a combination thereof. In some embodiments, the sacrificial material may be formed of, for example, boron nitride, silicon boron nitride, phosphorus boron nitride, boron carbon silicon nitride, or a combination thereof.

With reference to FIGS. 15 and 16, during the etching act of the first cycle of the opening-tuning process, an etching process may be performed to remove a portion of the first sacrificial layer 711, forming the first intermediate opening 711O. The residual first sacrificial layer 711 may primarily adhere to a sidewall of the cell contact opening 401O. In the current stage, an exposed portion within the cell contact opening 401O may still include the isolation layer 103 and the impurity region 105. In some embodiments, the first intermediate opening 711O may have a circular cross-sectional profile from a top-view perspective, but is not limited thereto. In some embodiments, the first intermediate opening 711O may have a diameter (or dimension) D1.

With reference to FIG. 17, during the deposition act of a second cycle of the opening-tuning process, additional sacrificial material may be conformally deposited over the top dielectric layer 115 to transform the first sacrificial layer 711 into the second sacrificial layer 713. In the current stage, a base of the first intermediate opening 711O may be filled, leaving sidewalls and a bottom of the cell contact opening 401O completely covered.

With reference to FIGS. 18 and 19, during the etching act of the second cycle of the opening-tuning process, an etching process may be performed to remove a portion of the second sacrificial layer 713, thereby forming the second intermediate opening 713O. The residual second sacrificial layer 713 may primarily adhere to the sidewalls of the cell contact opening 401O. The residual second sacrificial layer 713 may be thicker than the residual first sacrificial layer 711. In the current stage, an exposed portion within the cell contact opening 401O may include only the impurity region 105. In some embodiments, the second intermediate opening 713O may have a circular cross-sectional profile from a top-view perspective, but is not limited thereto. In some embodiments, the second intermediate opening 713O may have a diameter (or dimension) D2. The diameter D2 of the second intermediate opening 713O may be less than the diameter D1 of the first intermediate opening 711O.

Alternatively, in some embodiments, the exposed portion within the cell contact opening 401O may include both the impurity region 105 and the isolation layer 103 after the formation of the second intermediate opening 713O (not shown). However, an area of the exposed portion within the cell contact opening 401O after the formation of the second intermediate opening 713O may be less than an area of the exposed portion within the cell contact opening 401O after the formation of the first intermediate opening 711O.

In some embodiments, a planarization process, such as chemical mechanical polishing, may be performed until a top surface of the top dielectric layer 115 is exposed to remove excess material and provide a substantially flat surface for subsequent processing steps. In some embodiments, the planarization process may be optional.

In some embodiments, additional cycles of the opening-tuning process may be performed until a required diameter (or dimension) of the intermediate opening is achieved. In some embodiments, only one cycle of the opening-tuning process is performed to achieve the required diameter of the intermediate opening.

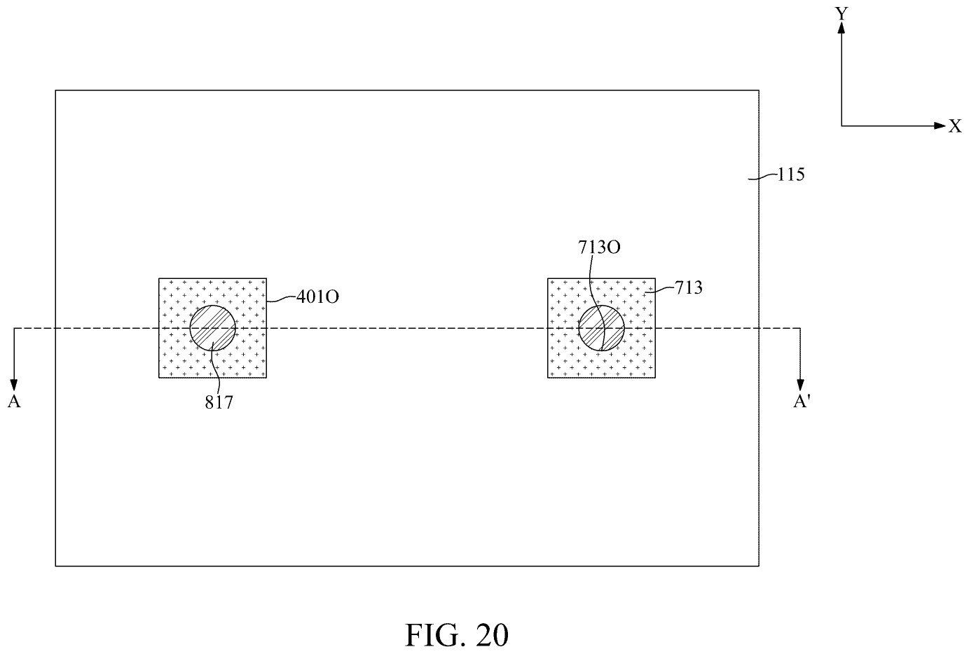

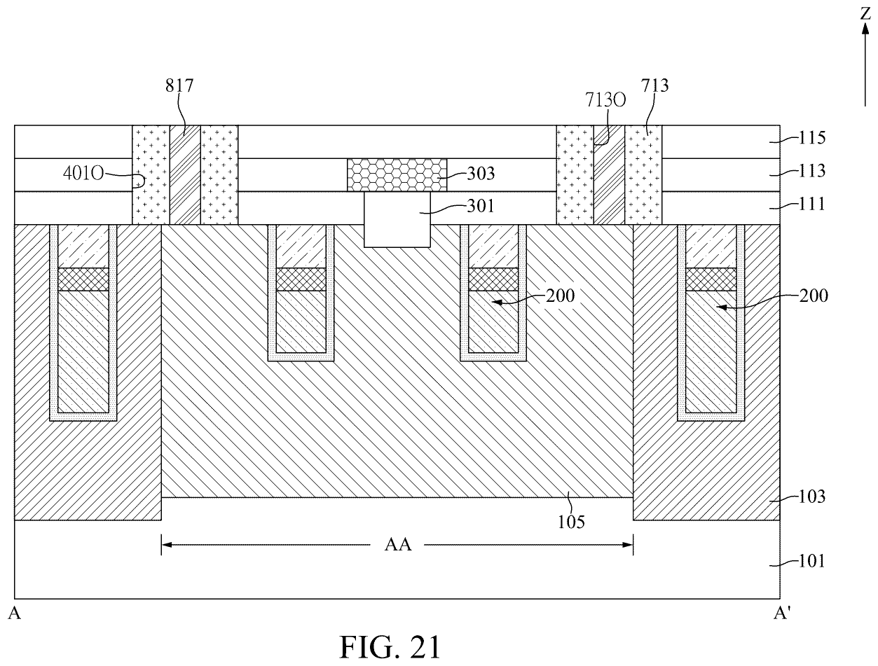

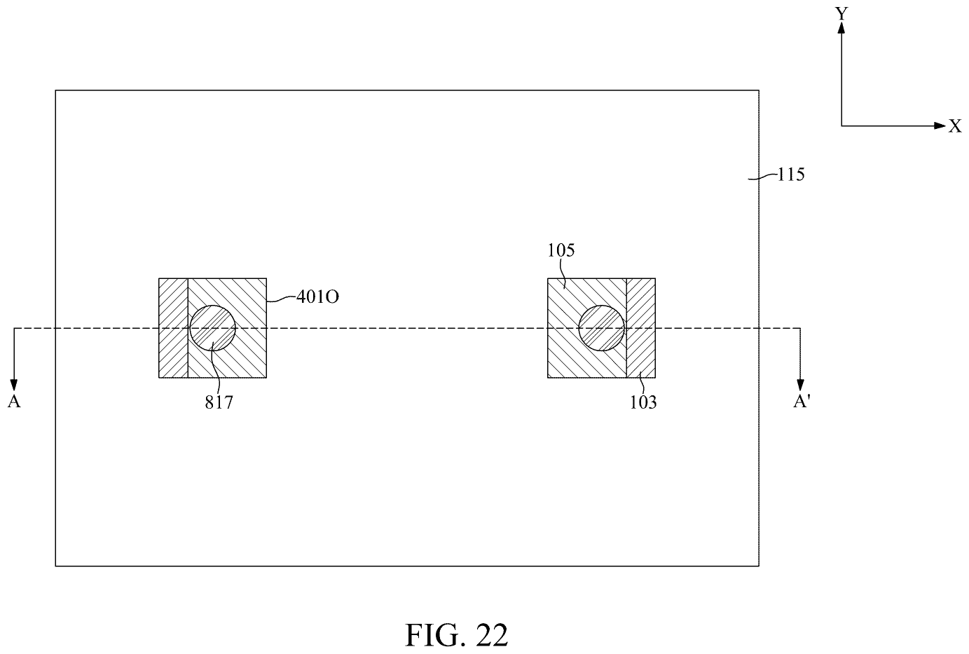

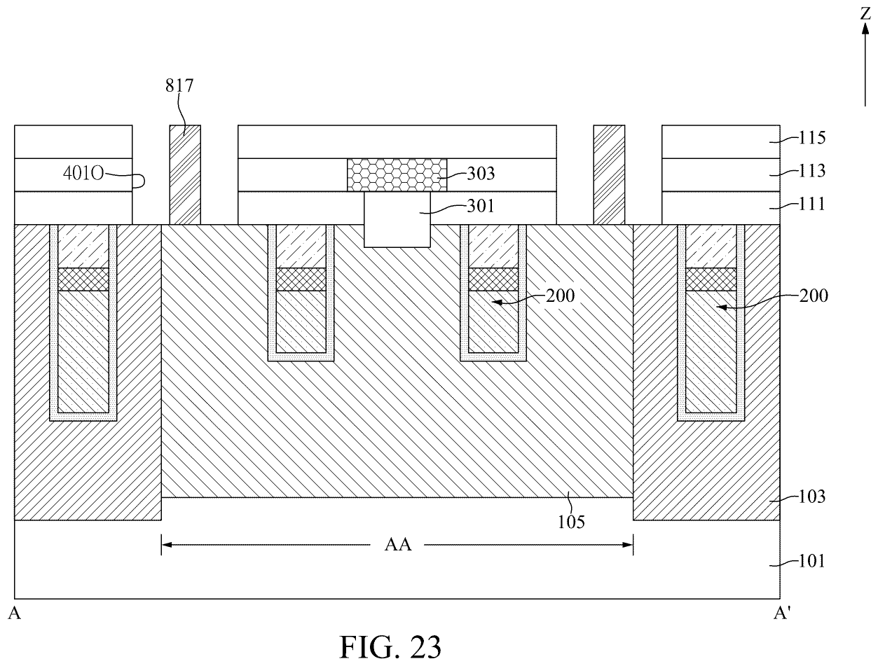

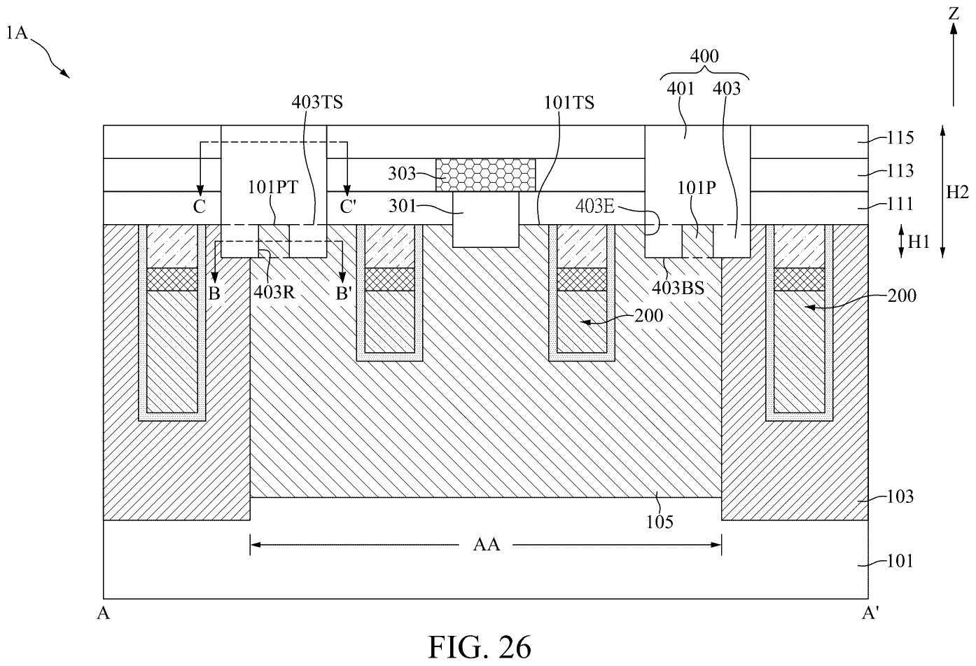

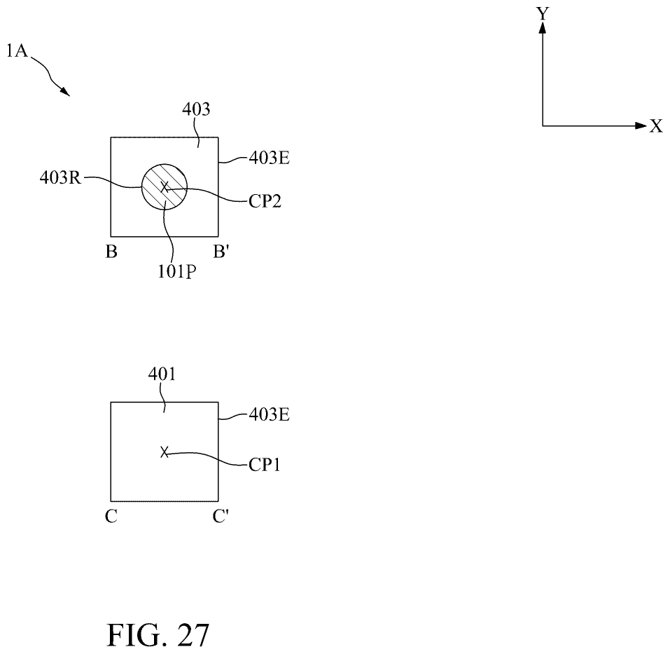

FIG. 20 illustrates, in a schematic top-view diagram, an intermediate semiconductor device in accordance with one embodiment of the present disclosure. FIG. 21 is a schematic cross-sectional view diagram taken along a line A-A′ in FIG. 20. FIG. 22 illustrates, in a schematic top-view diagram, an intermediate semiconductor device in accordance with one embodiment of the present disclosure. FIGS. 23 to 26 are schematic cross-sectional view diagrams taken along a line A-A′ in FIG. 22 illustrating a process for fabricating the semiconductor device 1A in accordance with one embodiment of the present disclosure. FIG. 27 is a schematic cross-sectional view diagram taken along lines B-B′ and C-C′ in FIG. 26.

With reference to FIG. 1 and FIGS. 20 to 27, in step S15, a plurality of blocking layers 817 may be formed in the plurality of second intermediate openings 713O, the second sacrificial layer 713 may be removed, the plurality of cell contact openings 401O may be deepened to form a plurality of extended cell contact openings 403E, the plurality of blocking layers 817 may be removed, and a plurality of contact structures 400 may be formed in the plurality of extended cell contact openings 403E.

For brevity, clarity, and convenience of description, only one blocking layer 817 is described.

With reference to FIGS. 20 and 21, the blocking layer 817 may completely fill the second intermediate opening 713O. In some embodiments, top surfaces of the blocking layer 817 and the second sacrificial layer 713 and the top surface of the top dielectric layer 115 may be substantially coplanar. In some embodiments, the blocking layer 817 may be formed of a material having etching selectivity to the second sacrificial layer 713 and the top dielectric layer 115. In some embodiments, the blocking layer 817 may be a photoresist layer.

Alternatively, in some embodiments, the top surface of the blocking layer 817 may be lower than a top surface of the second sacrificial layer 713 or the top surface of the top dielectric layer 115 (not shown).

With reference to FIGS. 22 and 23, the second sacrificial layer 713 may be removed. In some embodiments, the removal of the second sacrificial layer 713 may be achieved by an etching process such as a wet etching process. In some embodiments, during the wet etching process, a ratio of an etching rate of the second sacrificial layer 713 to an etching rate of the blocking layer 817 may be between about 100:1 and about 2:1, between about 15:1 and about 2:1, or between about 10:1 and about 2:1. In some embodiments, during the wet etching process, a ratio of the etching rate the second sacrificial layer 713 to an etching rate of the top dielectric layer 115 may be between about 100:1 and about 2:1, between about 15:1 and about 2:1, or between about 10:1 and about 2:1.

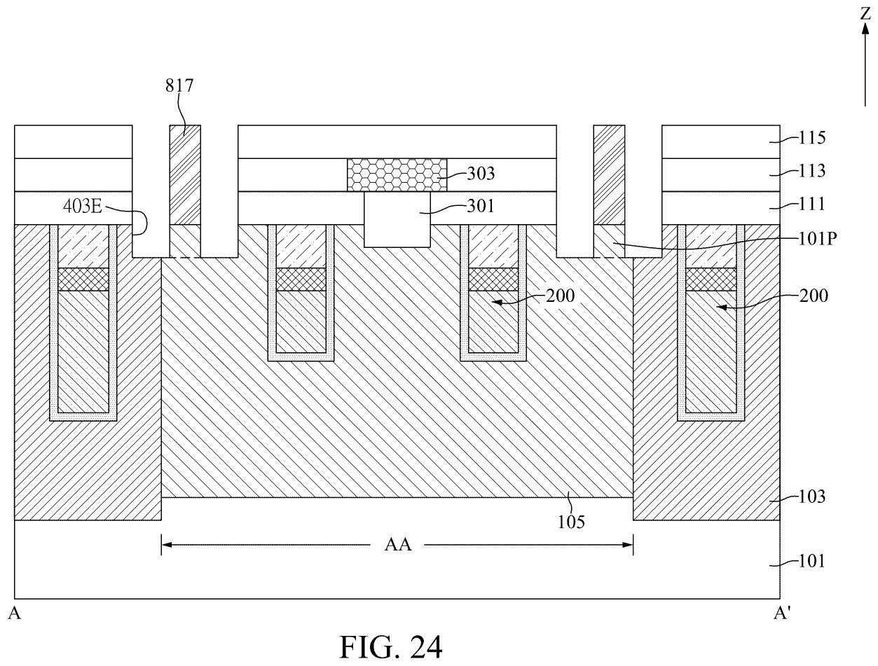

With reference to FIG. 24, the cell contact opening 401O may be deepened toward the substrate 101 using an etching process, such as an anisotropic dry etching process. The anisotropic dry etching process may employ the blocking layer 817 as a mask. After the anisotropic dry etching process is performed, the cell contact opening 401O may be extended to form an extended cell contact opening 403E. A lower section of the extended cell contact opening 403E may enclose a protruding portion 101P of the impurity region 105, which is shielded by the blocking layer 817.

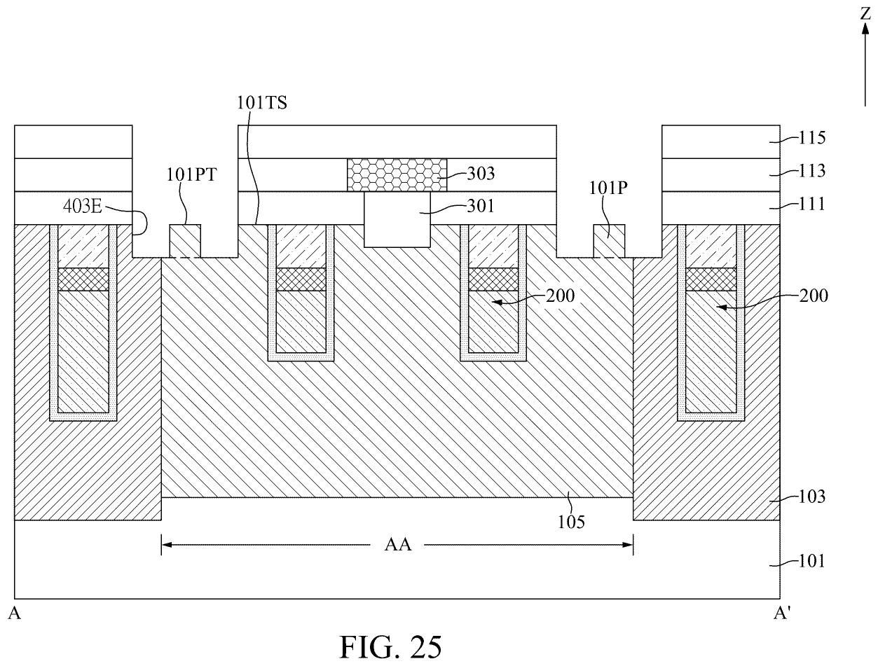

With reference to FIG. 25, the blocking layer 817 may be removed by, for example, an ashing process or an etching process. In some embodiments, a top surface 101PT of the protruding portion 101P and the top surface 101TS of the substrate 101 may be substantially coplanar. In some embodiments, the top surface 101PT of the protruding portion 101P may be slightly lower than the top surface 101PT of the substrate 101 due to consumption of the protruding portion 101P during the removal of the blocking layer 817 (not shown).

With reference to FIGS. 26 and 27, a conductive material may be deposited to completely fill the extended cell contact opening 403E. A planarization process, such as chemical mechanical polishing, may be performed until a top surface of the top dielectric layer 115 is exposed to remove excess material, provide a substantially flat surface for subsequent processing steps, and concurrently form a plurality of contact structures 400. In some embodiments, the conductive material may be, for example, tungsten, cobalt, zirconium, tantalum, titanium, aluminum, ruthenium, copper, metal carbides (e.g., tantalum carbide, titanium carbide, or tantalum magnesium carbide), metal nitrides (e.g., titanium nitride), transition metal aluminides, or a combination thereof.

For brevity, clarity, and convenience of description, only one contact structure 400 is described.

In some embodiments, the contact structure 400 may include a body portion 401 and an extending portion 403. The extending portion 403 may be disposed in a lower section of the extended cell contact opening 403E and encloses the protruding portion 101P of the impurity region 105. In some embodiments, a top surface 403TS of the extending portion 403, the top surface 101PT of the protruding portion 101P and the top surface 101TS of the substrate 101 may be substantially coplanar. In some embodiments, a bottom surface 403BS of the extending portion 403 may be substantially flat. In some embodiments, the extending portion 403 may have a square-ring-shaped cross-sectional profile from a top-view perspective.

The body portion 401 may be formed on the extending portion 403 and the protruding portion 101P. In some embodiments, the body portion 401 may have a square cross-sectional profile from a top-view perspective. In some embodiments, the body portion 401 may have a rectangular cross-sectional profile from a top-view perspective (not shown). In some embodiments, a ratio of a height H1 of the extending portion 403 to a height H2 of the contact structure 400 may be between about 0.05 and about 0.30, between about 0.10 and about 0.30, or between about 0.15 and about 0.20.

The extending portion 403 may extend from the body portion 401 toward the substrate 101. A groove 403R may be recessed into the bottom surface 403BS of the extending portion 403 and is recessed toward the body portion 401. The groove 403R may accommodate the protruding portion 101P, which directly contacts the body portion 401. In some embodiments, a center point CP1 (shown as a cross mark) of the body portion 401 may align with a center point CP2 (shown as a cross mark) of the groove from a top-view perspective. The center point CP2 of the groove may be referred to as the center point CP2 of the protruding portion 101P.

In the description of the present disclosure, an x-y-z coordinate system is used, wherein x and y refer to directions within a plane parallel to a major surface of a structure, and z refers to a direction perpendicular to the plane; one feature is aligned with another feature when such features have substantially same (x, y) coordinates.

A contact area of the contact structure 400 may be increased by employing the extending portion 403. As a result, performance of the semiconductor device 1A is improved.

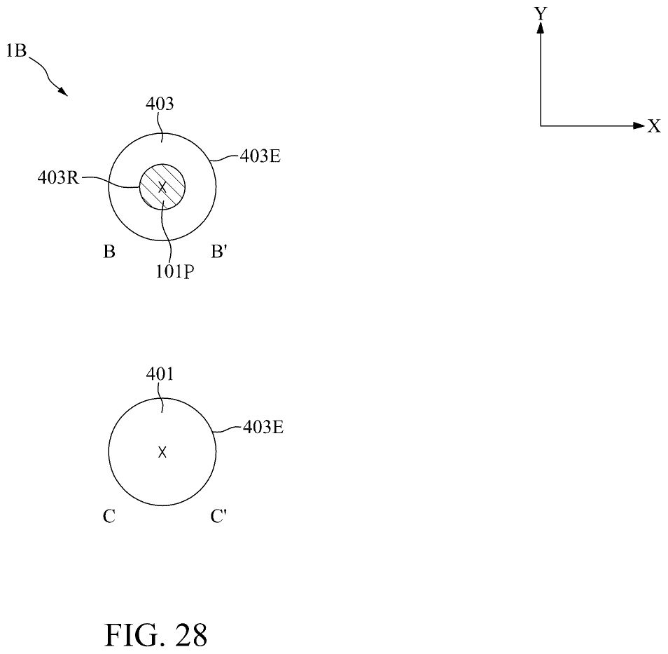

FIG. 28 illustrates, in schematic cross-sectional view diagrams, a body portion 401 and an extending portion 403 of a semiconductor device 1B in accordance with another embodiment of the present disclosure.

With reference to FIG. 28, the semiconductor device 1B may have a structure similar to that illustrated in FIG. 27. Elements in FIG. 28 that are same as or similar to elements in FIG. 27 are marked with similar reference numbers and duplicative descriptions are omitted.

In the semiconductor device 1B, the body portion 401 may have a circular cross-sectional profile from a top-view perspective. The extending portion 403 may have a ring-shaped cross-sectional profile from a top-view perspective.

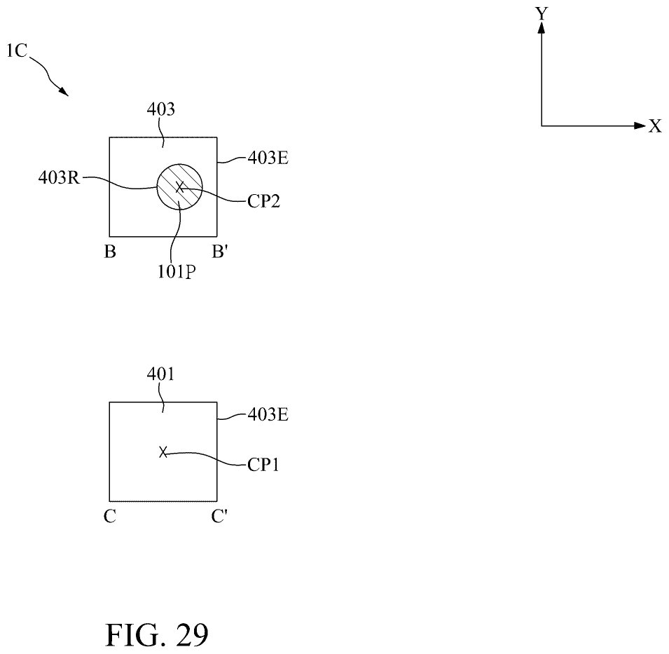

FIG. 29 illustrates, in schematic cross-sectional view diagrams, a body portion 401 and an extending portion 403 of a semiconductor device 1C in accordance with another embodiment of the present disclosure.

With reference to FIG. 29, the semiconductor device 1C may have a structure similar to that illustrated in FIG. 27. Elements in FIG. 29 that are same as or similar to elements in FIG. 27 are marked with similar reference numbers and duplicative descriptions are omitted.

In some embodiments, in the semiconductor device 1C, a center point CP1 of the body portion 401 does not align with a center point CP2 of the groove (or a center point CP2 of the protruding portion 101P) from a top-view perspective.

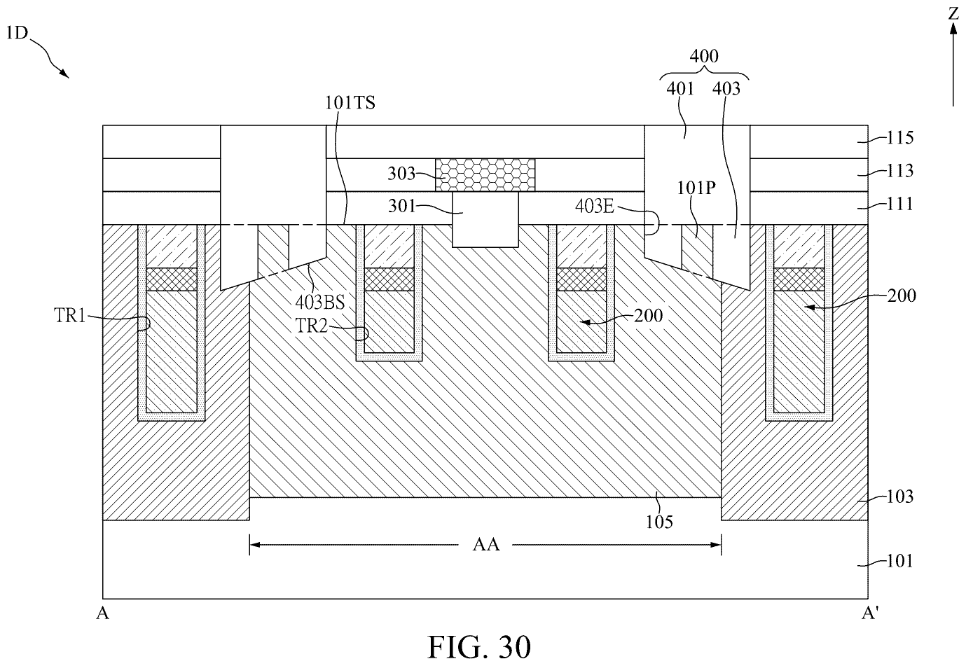

FIG. 30 illustrates, in a schematic cross-sectional view diagram, a semiconductor device 1D in accordance with another embodiment of the present disclosure.

With reference to FIG. 30, the semiconductor device 1D may have a structure similar to that illustrated in FIG. 27. Elements in FIG. 30 that are same as or similar to elements in FIG. 27 are marked with similar reference numbers and duplicative descriptions are omitted.

In the semiconductor device 1D, a bottom surface 403BS of the extending portion 403 may be inclined with respect to a top surface 101TS of the substrate 101. In some embodiments, the bottom surface 403BS near the word line structure 200 disposed in the trench TR2 may be higher than the bottom surface 403BS near the word line structure 200 disposed in the trench TR1.

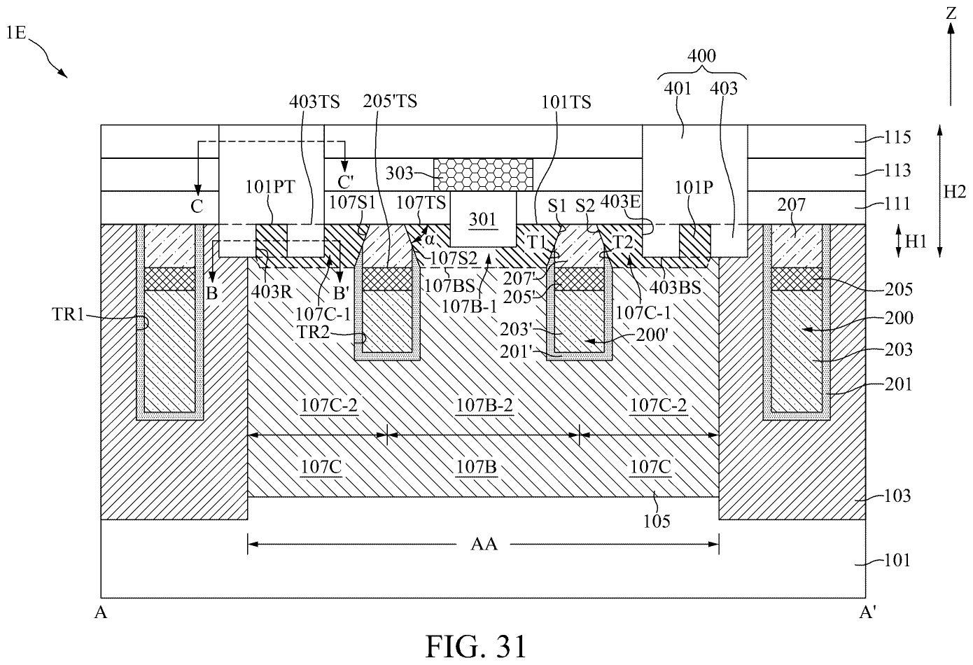

FIG. 31 illustrates, in a schematic cross-sectional view diagram, a semiconductor device 1E in accordance with various embodiments of the present disclosure. The semiconductor device 1E in FIG. 31 may have a structure similar to that illustrated in FIG. 26. Elements in FIG. 31 that are same as or similar to elements in FIG. 26 are marked with similar reference numbers and duplicative descriptions are omitted.

With reference to FIG. 31, the semiconductor device 1E may comprise a plurality of first word line structures 200 and a plurality of second word line structures 200′ in the substrate 101, wherein the plurality of first word line structures 200 are disposed in a plurality of first trenches TR1 in an isolation layer 103, and the plurality of second word line structures 200′ are disposed in a plurality of second trenches TR2 in an impurity region 105 defined by the isolation layer 103. The first word line structure 200, which comprises a first word line dielectric layer 201, a first word line bottom conductive layer 203, a first word line top conductive layer 205 and a first word line capping layer 207, is same as the word line structure 200 in the trench TR1 in FIG. 26. The second word line structure 200′ comprises a second word line dielectric layer 201′, a second word line bottom conductive layer 203′, a second word line top conductive layer 205′ and a second word line capping layer 207′. The second word line bottom conductive layer 203′ and the second word line top conductive layer 205′ of the second word line structure 200′ are same as the word line bottom conductive layer 203 and the word line top conductive layer 205 of the word line structure 200 in the trench TR2 in FIG. 26, respectively. Compared to the word line dielectric layer 201 and the word line capping layer 207 in the trench TR2 in FIG. 26, the second word line dielectric layer 201′ comprises two inclined top surfaces T1, T2 opposite to each other, and the second word line capping layer 207′ comprises two tapering sidewalls S1, S2 opposite to each other.

In addition, with reference to FIG. 31, the semiconductor device 1E further comprises a plurality of impurity regions 107B, 107C disposed in the substrate 101. Each of the plurality of impurity regions 107B, 107C may comprise an upper portion 107B-1/107C-1 disposed in a top surface 101TS of the substrate 101 and a lower portion 107B-2/107C-2 disposed below the upper portion 107B-1/107C-1. In some embodiments, top surfaces 107TS of the upper portions 107B-1, 107C-1 are substantially coplanar with the top surface 101TS of the substrate 101. The upper portions 107B-1, 107C-1 may be separated by the plurality of second word line structures 200′, and the lower portions 107B-2, 107C-2, which are portions remaining after an etching process is performed on the impurity region 105, may be connected to each other. The upper portion 107B-1/107C-1 may have two tapering sidewalls 107S1, 107S2 opposite to each other. Horizontal distances between the two tapering sidewalls 107S1, 107S2 may gradually decrease from the top surface 107TS of the upper portions 107B-1, 107C-1 to a bottom surface 107BS of the upper portions 107B-1, 107C-1 along the direction Z. An angle α between any one of the tapering sidewalls S1/S2 and the main plane of the substrate 101 (i.e., the X-Y plane) may be between about 45 degrees and about 60 degrees. In some embodiments, the top surfaces 107TS of the upper portions 107B-1, 107C-1 are substantially parallel to the main plane of the substrate 101 (i.e., the X-Y plane). In some embodiments, a top surface 205′TS of the second word line top conductive layer 205′ of the second word line structure 200′ is lower than the top surfaces 107TS of the upper portions 107B-1, 107C-1, and the upper portion 107B-1/107C-1 of the impurity region 107B/107C has a tapered cross-sectional profile.

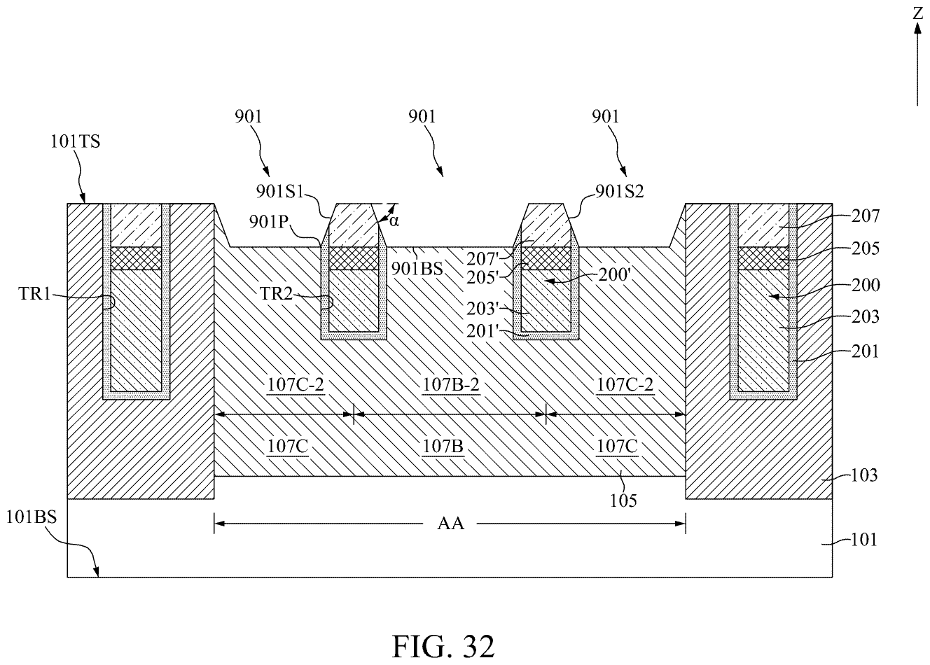

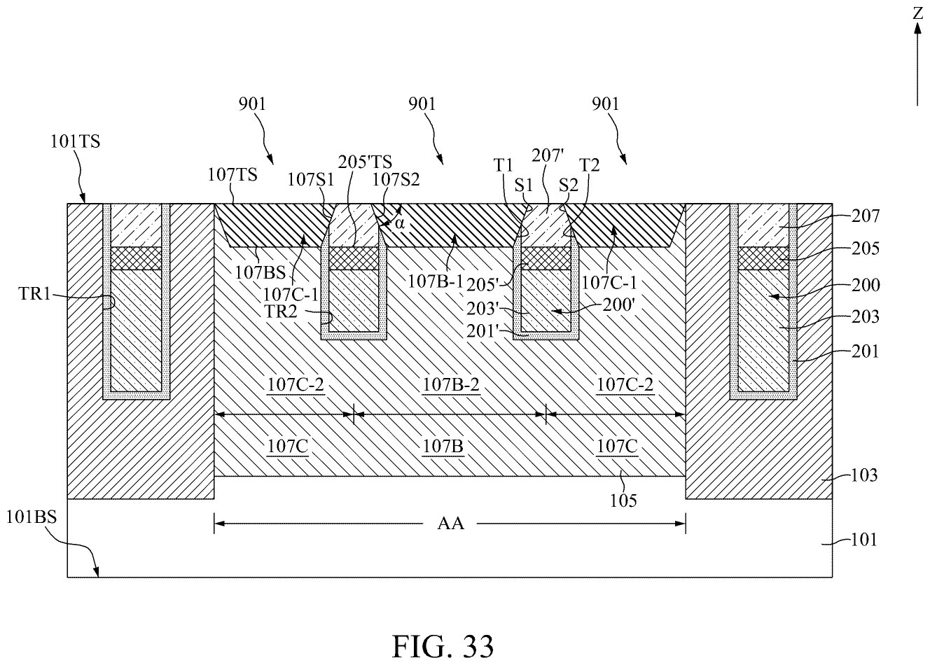

FIGS. 32 to 33 illustrate, in schematic cross-sectional view diagrams, a process for fabricating the semiconductor device 1E in accordance with various embodiment of the present disclosure.

With reference to FIG. 32, an etching process may be performed on the intermediate structure shown in FIG. 5 to remove portions of the impurity region 105 in the substrate 101, and to remove portions of the word line dielectric layer 201 and portions of the word line capping layer 207 in the trench TR2. As a result, a plurality of recesses 901, a plurality of first word line structures 200 (i.e., the word line structure 200 in the trench TR1 in FIG. 5), a plurality of second word line structures 200′ in the trenches TR2, and a plurality of lower portions 107B-2, 107C-2 of impurity regions 107B, 107C (i.e., the remaining portions of the impurity region 105 after the etching process is performed) are formed in the substrate 101. The recess 901 may have two tapering sidewalls 901S1, 901S2 opposite to each other. The recesses 901 may have a bottom surface 901BS, wherein a vertical position of the bottom surface 901BS is defined by an intersection point 901P of the tapering sidewall 901S1/901S2 and an outer side surface of the trench TR2. Horizontal distances between the two tapering sidewalls 901S1, 901S2 may gradually decrease from the top surface 101TS of the substrate 101 to the bottom surface 101BS of the recess 901 along the direction Z. An angle α between any one of the tapering sidewalls 901S1/901S2 and the main plane of the substrate 101 (i.e., the X-Y plane) may be between about 45 degrees and about 60 degrees. In some embodiments, the etching process may be an isotropic plasma dry etching process. In some embodiments, the etching process may be a wet etching process. In some embodiments, the top surface 101TS of the substrate 101 is substantially parallel to the main plane of the substrate 101 (i.e., the X-Y plane).

With reference to FIG. 33, an epitaxial growth process may be performed to fill the plurality of recesses 901 and concurrently form a plurality of upper portions 107B-1, 107C-1 of the impurity regions 107B, 107C. The epitaxial growth process may be chemical vapor deposition, atomic layer deposition, or molecular beam epitaxy. In some embodiments, a planarization process, such as chemical mechanical polishing, may be optionally performed to provide a substantially flat surface for subsequent processing steps.

A shape (or a structure) of the plurality of upper portions 107B-1, 107C-1 of the impurity regions 107B, 107C may be determined by the plurality of recesses 901. The upper portion 107B-1 may be located between the two second word line structures 200′. In some embodiments, the upper portions 107C-1 may be respectively correspondingly located opposite to the upper portion 107B with the two word line structures 200′ interposed therebetween. In other words, the upper portions 107B-1, 107C-1 may be separated by the second word line structures 200′. In some embodiments, the upper portions 107B-1, 107C-1 may have a top surface 107TS substantially coplanar with the top surface 101TS of the substrate 101, and a bottom surface 107BS substantially coplanar with the bottom surface 901BS of the recess 901.

In some embodiments, the upper portions 107B-1, 107C-1 may be formed of, for example, silicon phosphide (SiP), phosphorus-doped silicon carbon (SiCP), silicon carbide (SiC), silicon germanium (SiGe), silicon-germanium-tin alloy (SiGeSn), silicon-germanium-boron alloy (SiGeB), or another suitable semiconductor material.

In some embodiments, the upper portion 107B-1/107C-1 may be doped with a dopant such as phosphorus or boron. A dopant concentration of the upper portion 107B-1/107C-1 may be uniform. In some embodiments, a dopant concentration of the upper portion 107B-1/107C-1 may gradually increase from the bottom surface 107BS to the top surface 107TS. In some embodiments, a dopant concentration of the upper portions 107B-1, 107C-1 may be greater than a dopant concentration of the lower portions 107B-2, 107C-2.

A top surface 205′TS of the second word line top conductive layer 205′ of the second word line structure 200′ is lower than the top surface 107TS of the upper portions 107B-1, 107C-1 of the impurity regions 107B, 107C, and the impurity region 107B/107C has a tapered cross-sectional profile. In some embodiments, the top surface 205′TS of the second word line top conductive layer 205′ may be at a vertical position higher than the vertical position of the bottom surface 107BS of the upper portion 107. In some embodiments, the top surface 205′TS of the second word line top conductive layer 205′ and the bottom surface 107BS of the upper portion 107 may be at a same vertical position.

One aspect of the present disclosure provides a semiconductor device comprising a substrate; a word line structure comprising a word line electrode; an impurity region comprising an upper portion adjacent to the word line structure and a lower portion below the upper portion; and a contact structure comprising a body portion over the impurity region and an extending portion below the body portion. A top surface of the word line electrode of the word line structure is lower than a top surface of the upper portion of the impurity region, and the upper portion of the impurity region has a tapered cross-sectional profile.

Another aspect of the present disclosure provides a semiconductor device comprising a substrate with an isolation layer disposed therein; a plurality of impurity regions disposed in an active area defined by the isolation layer; and a plurality of first word line structures disposed in the isolation layer and a plurality of second word line structures disposed in the active area.

Another aspect of the present disclosure provides a semiconductor device comprising a substrate; a word line structure disposed in the substrate; an impurity region comprising an upper portion adjacent to the word line structure and a lower portion disposed below the upper portion; a bit line contact disposed in the substrate and protruding from the substrate; and a bit line disposed on the bit line contact. The word line structure comprises a word line dielectric layer contacting the lower portion of the impurity region, a word line electrode disposed on the word line dielectric layer, and a word line capping layer disposed on the word line electrode. A top surface of the word line electrode of the word line structure is lower than a top surface of the upper portion of the impurity region. The upper portion of the impurity region has a tapered cross-sectional profile.

Due to the design of the semiconductor device of the present disclosure, the extending portion may increase the contact area between the contact structure and the impurity region. As a result, the performance of the semiconductor device 1A is improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a word line structure comprising a word line electrode;
an impurity region comprising an upper portion adjacent to the word line structure and a lower portion below the upper portion; and
a contact structure comprising a body portion over the impurity region and an extending portion below the body portion;
wherein a top surface of the word line electrode of the word line structure is lower than a top surface of the upper portion of the impurity region, and the upper portion of the impurity region has a tapered cross-sectional profile.

2. The semiconductor device of claim 1, wherein the top surface of the upper portion is substantially coplanar with a top surface of the substrate.

3. The semiconductor device of claim 2, wherein the impurity region comprises two tapering sidewalls connected to the top surface of the upper portion of the impurity region.

4. The semiconductor device of claim 3, wherein an angle α between one of the two tapering sidewalls and the top surface of the upper portion of the impurity region is between about 45 degrees and about 60 degrees.

5. The semiconductor device of claim 1, wherein a dopant concentration of the upper portion is greater than a dopant concentration of the lower portion.

6. The semiconductor device of claim 5, wherein the dopant concentration of the upper portion gradually increases from a bottom surface of the upper portion to a top surface of the upper portion.

7. The semiconductor device of claim 1, wherein the word line structure further comprises a word line dielectric layer contacting the lower portion of the impurity region, and a word line capping layer disposed on the word line electrode.

8. The semiconductor device of claim 7, wherein the word line dielectric layer comprises two inclined top surfaces opposite to each other.

9. The semiconductor device of claim 7, wherein the word line capping layer comprises two tapering sidewalls opposite to each other.

10. The semiconductor device of claim 7, wherein the word line electrode is disposed on and surrounded by the word line dielectric layer.

11. The semiconductor device of claim 10, wherein the word line electrode comprises a word line top conductive layer and a word line bottom conductive layer below the word line top conductive layer.

12. The semiconductor device of claim 1, wherein the extending portion of the contact structure extends from the body portion and comprises a groove, wherein the groove is recessed into a bottom surface of the extending portion, is recessed toward the body portion, and exposes the body portion.

13. The semiconductor device of claim 1, wherein a ratio of a height of the extending portion to a height of the contact structure is between about 0.05 and about 0.30.

14. The semiconductor device of claim 12, wherein the body portion has a square cross-sectional profile from a top-view perspective.

15. The semiconductor device of claim 12, wherein the extending portion has a ring-shaped cross-sectional profile from a top-view perspective.
